(19) United States
(12) Patent Application Publication
(10) Pub. No.: US 2026/0326261 A1
(43) Pub. Date: Oct. 22, 2026

(54) MULTI-LAYER SUB PAD FOR CMP PROCESSES

(71) Applicant: Taiwan Semiconductor Manufacturing Co., Ltd., Hsinchu (TW)

(72) Inventors: Zih-Jian Chen, Taipei City (TW); Ting-Kui Chang, New Taipei City (TW); Ming-Hsiang Cheng, Hsinchu (TW); Yi-Chieh Hsieh, Kaohsiung City (TW); William Weilun Hong, Hsinchu (TW)

(21) Appl. No.: 19/725,347

(22) Filed: Jun. 30, 2026

Related U.S. Application Data
(63) Continuation of application No. 18/934,439, filed on Nov. 1, 2024.
(60) Provisional application No. 63/671,510, filed on Jul. 15, 2024.

(51) Int. Cl. B24B 37/22; B24B 37/24; B24B 37/26; B32B 3/30; B32B 7/12; B32B 27/08

(52) U.S. Cl. CPC B24B 37/22; B24B 37/24; B24B 37/26; B32B 3/30; B32B 7/12; B32B 27/08; B32B 2250/03; B32B 2307/536; B32B 2307/7376; B32B 2475/00

(57) ABSTRACT

An apparatus includes a top pad comprising a plurality of protrusions and a plurality of grooves between the plurality of protrusions, a first adhesive film underlying the top pad, and a first anti-deformation layer underlying and attached to the top pad through the first adhesive film. The first anti-deformation layer has a first hardness. The apparatus further includes a second adhesive film underlying the first anti-deformation layer, and a main support layer underlying and attached to the top pad through the second adhesive film. The main support layer has a second hardness lower than the first hardness.

### PRIORITY CLAIM AND CROSS-REFERENCE

This application is a continuation of U.S. patent application Ser. No. 18/934,439, filed Nov. 1, 2024 and entitled “MULTI-LAYER SUB PAD FOR CMP PROCESSES,” which claims the benefit of U.S. Provisional Application No. 63/671,510, filed on Jul. 15, 2024, and entitled “MULTIPLE SUB PAD STACKING FOR CMP PROCESS,” which application are hereby incorporated herein by reference.

### BACKGROUND

As advanced manufacturing processes continue to progress, the pursuit of smaller pitches necessitated an increasing emphasis on the planarization of wafer surfaces, particularly in photolithography processes. This underscores the growing importance of precision in Chemical Mechanical Polishing (CMP) processes. The apparatus for the CMP processes for achieving the precision in the CMP processes is thus needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a bottom view of a retaining ring and a sub pad of an apparatus for Chemical Mechanical Polishing (CMP) processes in accordance with some embodiments.

FIG. 2 illustrates a cross-sectional view of a polish pad including a multiplane sub pad in accordance with some embodiments.

FIG. 3 illustrates a cross-sectional view of a polishing head pressed on a polish pad including a multiplane sub pad in accordance with some embodiments.

FIG. 4 illustrates the layers in a polish pad including a multiplane sub pad in accordance with some embodiments.

FIG. 5 illustrates a cross-sectional view of a polish pad including a groove-containing sub pad in accordance with some embodiments.

FIG. 6 illustrates a cross-sectional view of a polishing head pressed on a polish pad including a groove-containing sub pad in accordance with some embodiments.

FIG. 7 illustrates the layers in a polish pad including a groove-containing sub pad in accordance with some embodiments.

FIG. 8 illustrates a cross-sectional view of a polish pad including a hybrid sub pad in accordance with some embodiments.

FIG. 9 illustrates a cross-sectional view of a polishing head pressed on a polish pad including a hybrid sub pad in accordance with some embodiments.

FIG. 10 illustrates the layers in a polish pad including a hybrid sub pad in accordance with some embodiments.

FIGS. 11-19 illustrate the views of some layers in sub pads in accordance with some embodiments.

FIGS. 20-22 illustrate the cross-sectional views of groove-containing main support layers in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Polish pads including multi-layer sub pads are provided, and are used for polishing wafer in Chemical Mechanical Polish (CMP) processes. In accordance with some embodiments, a multi-layer sub pad may include a polishing layer, and an anti-deformation layer under the polishing layer. The multi-layer sub pad may further (or alternatively) include a grooved main support layer under the polishing layer. The anti-deformation layer is more rigid than the overlying polishing layer and an underling main support layer. The anti-deformation layer thus has high resistance to deformation and retaining ring induced sub-pad compression. The grooves in the grooved main support layer are more densely distributed than the polishing layer, and thus result in characteristics similar to independent cylinders. Accordingly, the grooved main support layer may provide the polishing layer with additional support. The anti-deformation layer and the grooved main support layer may also be combined as a hybrid layer in the sub pad.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

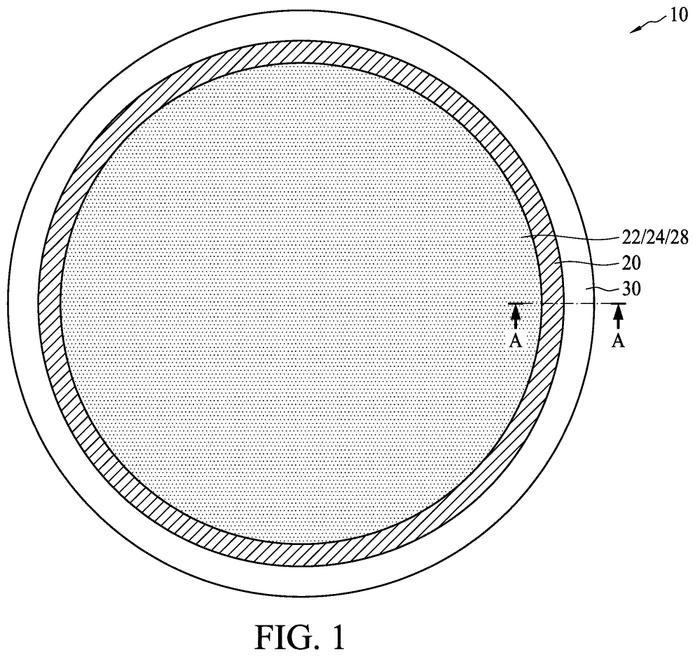

FIG. 1 illustrates a bottom view of a portion of a polishing apparatus 10 in accordance with some embodiments. Some of the features as shown in FIG. 1 are also shown in the cross-sectional view as shown in FIG. 3. A retaining ring 20 is formed as a ring, and encircles a circular region. As shown in FIGS. 1 and 3, a top ring 22 is formed as a circular pad, and is secured in the retaining ring 20. Membrane 24 is underlying and attached to the top ring 22, and is used to buffer and to provide uniform suppression force to the underlying wafer 28. Retaining ring 20, top ring 22, and membrane 24 collectively form parts of polishing head 26.

Wafer 28 is encircled by retaining ring 20 and is underlying and attached to membrane 24, for example, through the sucking force of vacuum. During CMP processes, the retaining ring 20 may prevent wafer 28 from slipping out of the region directly underlying membrane 24.

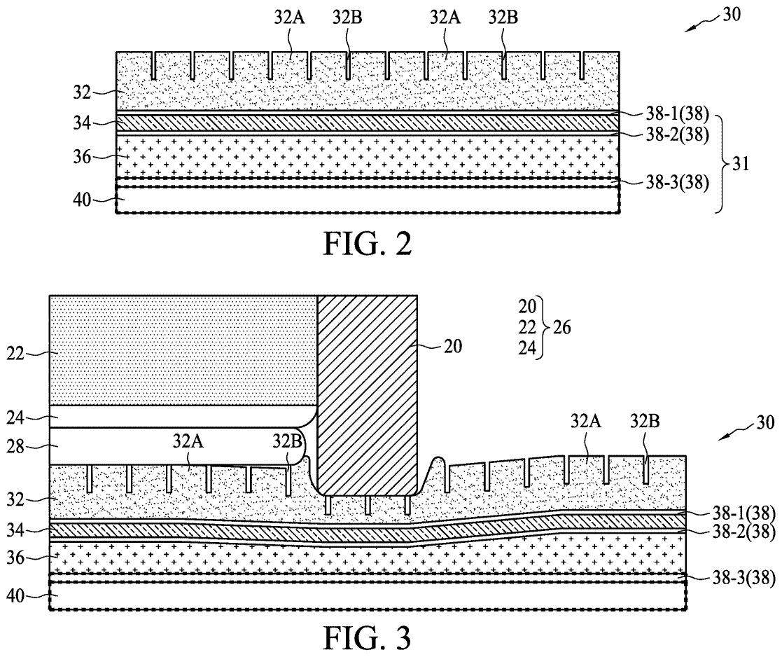

FIG. 2 illustrates a cross-sectional view of a polish pad 30, which includes a multiplane sub pad 31 in accordance with some embodiments. The polish pad 30 includes top pad 32 (alternatively referred to as polishing layer 32) at the top. The top pad 32 comprises protrusions 32A and grooves 32B between protrusions 32A. The top pad 32 is configured to hold slurry and abrasive in grooves 32B, so that the wafer 28 (FIGS. 1 and 3) in contact with the top pad 32 may be polished and etched during CMP processes.

Adhesive films 38 (include 38-1, 38-2, 38-3, and the like) are used to adhere the plurality of layers in polish pad 30 together. The properties of some of adhesive films 38 are discussed below as an example. Unless specified otherwise, other adhesive films throughout the description may be selected from the same group of candidate materials and have same materials (and thus have the same properties) as the discussed adhesive films 38.

In accordance with some embodiments, adhesive films 38 may have a Shore A hardness in the range between about 1 and about 100. The thicknesses of adhesive films 38 may be in the range between about 0.025 mm and about 2.54 mm. In accordance with some embodiments in which adhesive films 38 have high-enough Shore A hardness, adhesive films 38 help to provide support to the sub pad 31.

Adhesive film 38-1 is under top pad 32. In accordance with some embodiments, adhesive film 38-1 comprises or may be formed of a material selected from the group consisting of acrylics, epoxies, polyurethanes, and combinations thereof. Adhesive film 38-1 may alternatively comprise other synthetic materials or the combination of other synthetic materials with the aforementioned materials.

Multiplane sub pad 31 is underlying and attached to top pad 32 through adhesive film 38-1. Multiplane sub pad 31 includes anti-deformation layer 34, main support layer 36, and may or may not include stabilizing layer 40 in accordance with some embodiments. Main support layer 36 and stabilizing layer 40 are also individually and collectively referred to as support layers.

Anti-deformation layer 34 may be adhered to top pad 32 through adhesive films 38-1. In accordance with some embodiments, anti-deformation layer 34 is more rigid than the overlying top pad 32 and the underlying support layers 36 and/or 40, endowing it with excellent deformation resistance.

Anti-deformation layer 34 has the function of resisting the down force applied by polish head 26, and has the function of reducing the deformation of the polish pad 30. Anti-deformation layer 34 has high toughness and supportiveness. Accordingly, when subjected to the downward pressure from the retaining ring 20 (FIG. 3), anti-deformation layer 34 may effectively suppress deformation and create a buffering effect. This reduces the degree of retain-ring-induced sub-pad compression, and hence enhanced uniformity in wafer surface flatness may be achieved.

In accordance with some embodiments, anti-deformation layer 34 may comprise or may be formed of a material comprising a polymer (such as polyurethane, polymethylmethacrylate, polytetrafluoroethylene, or the like), natural resins, and/or other synthetic resins. In accordance with some embodiments, the anti-deformation layer 34 has a Shore A hardness in the range between about 40 and about 100. The compressibility of anti-deformation layer 34 may be in the range between about 10% and about 60%, and may be smaller than the compressibility values of top pad 32, main support layer 36, and stabilizing layer 40. The compressibility reflects the volume reduction of a material when under pressure.

In accordance with some embodiments, anti-deformation layer 34 may include a closed cells foam. Alternatively, anti-deformation layer 34 may include fibers and continuous channels between the fibers. Anti-deformation layer 34 may also include vertically oriented and open pores in accordance with yet alternative embodiments.

Adhesive film 38-2 is underlying anti-deformation layer 34, and may be formed of a material selected from the same group of candidate materials of adhesive film 38-2.

Support layers are formed underlying the anti-deformation layer 34. In accordance with some embodiments, the support layers comprise main support layer 36 and stabilizing layer 40. Stabilizing layer 40 may or may not be formed, depending on whether main support layer 36 alone may provide enough support or not.

Main support layer 36 is under anti-deformation layer 34, and is attached to anti-deformation layer 34 through adhesive film 38-2. In accordance with some embodiments, main support layer 36 may comprise or may be formed of a material selected from the group consisting of a polymer (such as polyurethane, polymethylmethacrylate, polytetrafluoroethylene, or the like), a natural resin, and/or combinations thereof. Main support layer 36 may comprise other synthetic materials or the combination of other synthetic materials with the aforementioned materials.

Main support layer 36 may include one or more layers, with each of the layer(s) having a flat and porous structure. The porous structure of main support layer 36 may include closed cells foam, fibers and continuous channels between fibers, vertically oriented open pores, non-porous polymer sheet with surface macro-texture, or the like. The thickness of main support layer 36 may be in the range between about 0.51 and about 2.54 mm.

Main support layer 36 may have a Shore A hardness in the range between about 10 and about 60. Main support layer 36 may be softer than anti-deformation layer 34, with the hardness of the anti-deformation layer 34 being greater than the hardness of main support layer 36. For example, the Shore A hardness of main support layer 36 may be lower than the Shore A hardness of anti-deformation layer 34 by a difference greater than about 5, greater than about 10, or greater than about 30.

The main support layer 36, being softer than anti-deformation layer 34, may have a deflection value greater than the deflection values of anti-deformation layer 34 and stabilizing layer 40. For example, main support layer 36 may have a deflection value in the range between about 1.00 and about 2.41 mm. Also, the main support layer 36 may have a compressibility in a range between about 40% and about 95%, which is greater than the compressibility of anti-deformation layer 34, for example, with a difference ranging between about 10% and about 80%.

Adhesive film 38-3 is underlying main support layer 36. In accordance with some embodiments, adhesive film 38-3 comprises or may be formed of a material selected from the group consisting of acrylics, epoxies, polyurethanes, and combinations thereof. Adhesive film 38-3 may alternatively comprise other synthetic materials or the combination of other synthetic materials with the aforementioned materials.

Stabilizing layer 40 (when formed), is underlying, and is attached to main support layer 36 through adhesive film 38-3. In accordance with some embodiments, stabilizing layer 40 may be formed of or comprise a material selected from the group consisting of a polymer (such as polyurethane, polymethylmethacrylate, polytetrafluoroethylene, and/or the like), a natural resin, another synthetic resin, and combinations thereof. An adhesive film 38-3 is underlying main support layer 36, and may be formed of a material selected from the same group of candidate materials of adhesive film 38-2.

Stabilizing layer 40 has the function of providing long-lasting stability and support for quality polish processes. Stabilizing layer 40 may include one or more layers, and may have flat and porous structures. The thickness of stabilizing layer 40 may be in the range between about 0.51 and about 2.54 mm.

The stabilizing layer 40 may be more rigid than the main support layer 36. For example, the Shore A hardness of stabilizing layer 40 is greater than the Shore A hardness of main support layer 36. In accordance with some embodiments, the stabilizing layer 40 has a Shore A hardness in the range between about 40 and about 100.

Also, the deflection of stabilizing layer 40 may be lower than the deflection of the main support layer 36. In accordance with some embodiments, the deflection of stabilizing layer 40 may be in the range between about 0.25 mm and about 1.52 mm.

The compressibility of the stabilizing layer 40 may be smaller than the compressibility of the main support layer 36. For example, the compressibility of stabilizing layer 40 may be in the range between about 10% and about 60%.

FIG. 3 illustrates parts of the polishing head 26, wafer 28, and polish pad 30 in accordance with some embodiments. The cross-sectional view may be obtained from the cross-section A-A as shown in FIG. 1. As shown in FIG. 3, due to the down-force applied by the retaining ring 20 to the top pad 32, the top pad 32 and the underlying sub pad 31 are de-formed, and are pressed down.

Since anti-deformation layer 34 is rigid, the portion of anti-deformation layer 34 directly underlying retaining ring 20 has reduced deformation. As a result, the bottom surface of the portion of the top pad 32 directly underlying retaining ring 20 is de-formed less. The top surfaces of the portions of top pad 32 in the regions close to the wafer edges are thus pressed-down less. Accordingly, the contact between the top pad 32 and the edge portions of wafer 28 is improved and is more uniform.

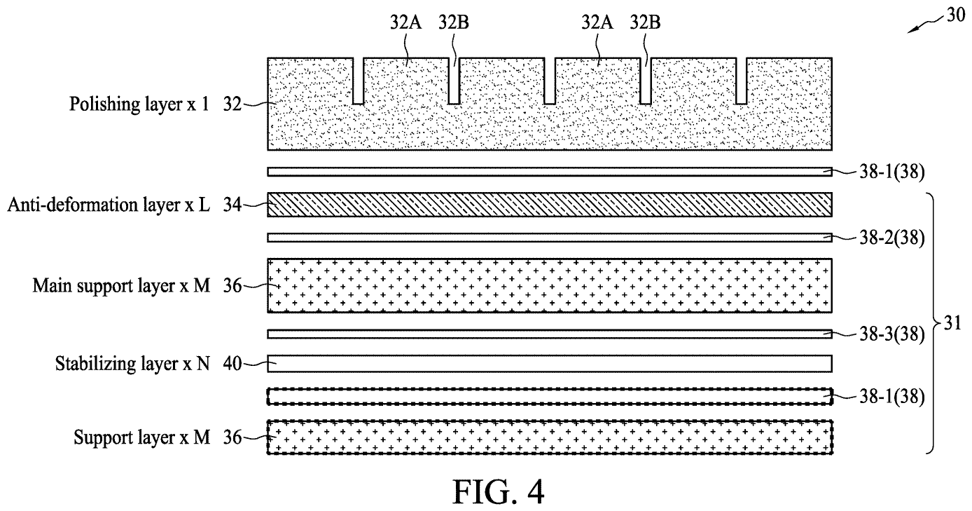

FIG. 4 illustrates the possible stacked layer scheme of a multiplane sub pad 31 as shown in FIGS. 2 and 3 in accordance with some embodiments. In accordance with some embodiments, the anti-deformation layer 34 has a single-layer structure. In accordance with alternative embodiments, the anti-deformation layer 34 has a multi-layer structure including a plurality of stacked anti-deformation layers 34. Additional adhesive films 38 may be between the stacked anti-deformation layers 34, and adhere the plurality of stacked anti-deformation layers 34 as a multi-layer structure. The number (L) of the stacked anti-deformation layers 34 may be any number ranging from 1 to 20.

In accordance with some embodiments, the main support layer 36 has a single-layer structure. In accordance with alternative embodiments, the main support layer 36 has a multi-layer structure including a plurality of stacked main support layers 36. Additional adhesive films 38 may be between the stacked main support layer 36, and adhere the plurality of stacked main support layers 36 as a multi-layer structure. The number (M) of the plurality of stacked main support layers 36 may be any number ranging from 1 to 20.

In accordance with some embodiments, the stabilizing layer 40 has a single-layer structure. In accordance with alternative embodiments, the stabilizing layer 40 has a multi-layer structure including a plurality of stacked stabilizing layers 40. Additional adhesive films 38 may be between the stacked stabilizing layer 40, and adhere the plurality of stacked stabilizing layers 40 as the multi-layer structure. The number (N) of the plurality of stacked stabilizing layer 40 may be any number ranging from 1 to 20.

In accordance with some embodiments in which one or both of anti-deformation layers 34 and main support layer 36 comprise a plurality of stacked layers, all of the anti-deformation layers 34 may be placed over all of the main support layers 36, regardless of the number of the anti-deformation layers 34 and the number of main support layers 36.

In accordance with alternative embodiments, one or a plurality of anti-deformation layers 34 and one or a plurality of main support layers 36 may be arranged from top to bottom as a unit, regardless of the number of the anti-deformation layers 34 and the number main support layer 36 in each unit. The unit may be repeated one or a plurality of times, for example, for up to about 10 times.

In accordance with some embodiments in which one or both of the main support layer 36 and stabilizing layers 40 comprise a plurality of stacked layers, all of the main support layers 36 are placed over all of the stabilizing layers 40, regardless of the number of the main support layer 36 and the stabilizing layers 40.

In accordance with alternative embodiments, one or a plurality of main support layers 36 and one or a plurality of stabilizing layers 40 may be arranged from top to bottom as a unit, regardless of the number of the main support layers 36 and the number the stabilizing layers 40. The unit may be repeated one or a plurality of times, for example, for up to about 10 times. For example, FIG. 4 illustrates that additional main support layers 36 may be formed under the stabilizing layer(s) 40, which main support layers 36 are in the repeating unit(s). While not shown, more stabilizing layer 40 in the repeating unit(s) may be further formed underlying the illustrated bottom ones of the main support layers 36.

In accordance with some embodiments in which stabilizing layer 40 is not formed, the respective sub pad 31 may be a two-layer sub pad. In these embodiments, the main support layer 36 may be a single-layer or a unit comprising a plurality of main support layers adhered together as a unit.

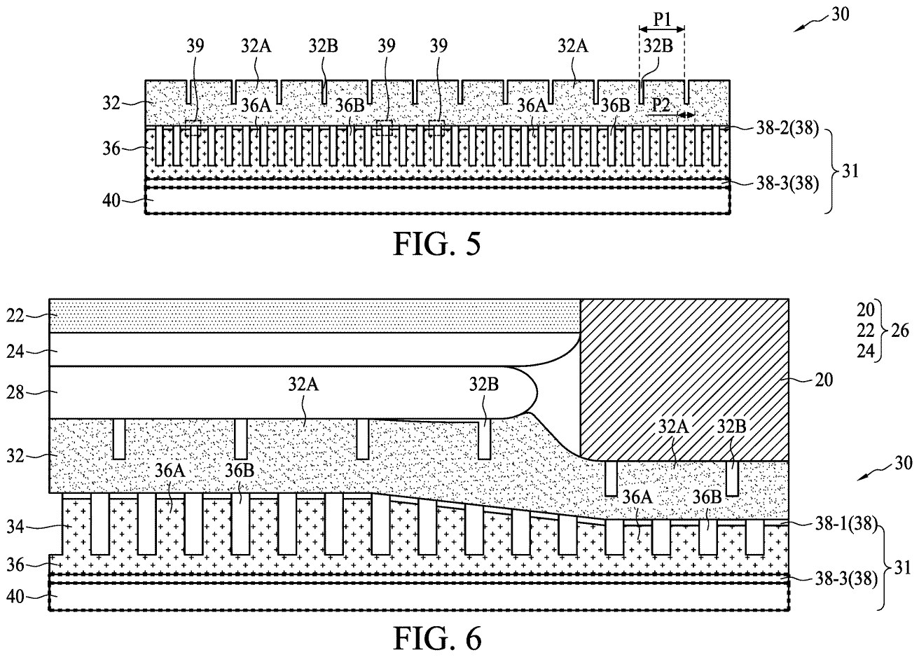

FIG. 5 illustrates the cross-sectional view of a groove-containing sub pad 31 in accordance with alternative embodiments. Unless specified otherwise, the materials, the structures, and the formation processes of the components in these embodiments and subsequently discussed embodiments as shown in FIGS. 6 through 22 are essentially the same as the like components denoted by like reference numerals in the preceding embodiments. The details regarding the materials, the structures, and the formation processes provided in each of the embodiments throughout the description may be applied to any other embodiment whenever applicable.

The polish pad 30 as shown in FIG. 5 is essentially the same as the polish pad 30 as shown in FIG. 2, except that the flat main support layer 36 in FIG. 2 is replaced with a main support layer 36 that is grooved (which is referred to as grooved main support layer 36 hereinafter), and anti-deformation layer 34 is not used. The groove-containing sub pad 31 thus includes grooved main support layer 36, and may or may not include stabilizing layer 40 in accordance with some embodiments. The rest of the features in FIG. 5 may be essentially the same as the corresponding features as shown in FIGS. 2 through 5, and the details of these features may be found referring to the discussion of FIGS. 2 through 4.

In accordance with some embodiments, the grooved main support layer 36 comprises a plurality of protrusions 36A and a plurality of grooves 36B separating the protrusions 36A. The top-view shapes of protrusions 36A may include discrete cylinders, protrusion rings, or the like. The top-view shapes of grooves 36B may include groove rings, groove grids, or the like. The shapes of the protrusions 36A and grooves 36B may be found in subsequently discussed figures.

In accordance with some embodiments, the protrusions 36A throughout the grooved main support layer 36 have equal widths, and/or the grooves 36B throughout the grooved main support layer 36 have equal widths. In accordance with alternative embodiments, the protrusions 36A may have different widths, and/or the grooves 36B may have different widths, in order to improve the uniformity of the polishing process. The protrusions 36A and grooves 36B, based on their widths, may be divided into a plurality of zones (groups), with the widths of the protrusions 36A (or grooves 36B) in the same zone being equal to each other, and the widths of the protrusions 36A (or grooves 36B) in different zones being different from each other. The different zones correspond to different positions on the wafer surface. In accordance with some embodiments, the widths of grooves 36B may be in the range between about 0.25 mm and about 2.54 mm.

The grooved main support layer 36 may include one or more layers, with each of the layer(s) having a flat (but with grooves) and porous structure. The porous structure of the grooved main support layer 36 may include closed cells foam, fibers and continuous channels between fibers, vertically oriented open pores, non-porous polymer sheet with surface macro-texture, or the like. The material of the grooved main support layer 36 may be selected from the same group of candidate materials for forming the main support layer 36 as shown in FIG. 2.

In accordance with some embodiments, the grooves 36B in main support layer 36 are more densely distributed than the grooves 32B of the top pad 32. For example, the pitch P1 of the grooves 32B may be greater than the pitch P2 of the grooves 36B. The dense protrusions 36A and grooves 36B of grooved main support layer 36 result in the characteristics of the grooved main support layer 36 to be similar to that of independent cylinders, and has the ability of isolating the downward force.

Adhesive film 38-2 adheres the grooved main support layer 36 to top pad 32. In accordance with some embodiments, the adhesive film 38-2 is a continuous film when viewed in the cross-section. Accordingly, the adhesive film 38-2 may be a blanket layer extending to opposite edges of top pad 32 and the grooved main support layer 36. Therefore, some portions of the adhesive film 38-2, which are in the illustrated regions 39 as an example, are directly over and exposed to grooves 36B.

In accordance with alternative embodiments, the adhesive film 38-2 comprises discrete portions overlaying (overlapping) protrusions 36A, but does not include portions (in regions 39) overlapping at least some part, or all of, grooves 36B. Accordingly, the bottom surface of top pad 32 may be exposed to grooves 36B.

FIG. 6 illustrates parts of the polishing head 26, wafer 28, and polish pad 30 in accordance with some embodiments. The cross-sectional view may be obtained from the cross-section A-A as shown in FIG. 1. As shown in FIG. 6, due to the down-force applied by the retaining ring 20 to the top pad 32, the top pad 32 and the underlying sub pad 31 are de-formed, and are pressed down. The grooved main support layer 36 may carry the top pad 32 and disperse the down-force applied from polish head 26. The grooved main support layer 36 shares the deformation with top pad 32, and the deformation of the top pad 32 may be reduced. The grooved main support layer 36 has high toughness and supportiveness, and may provide shock absorption and disturbance resistance capabilities. The grooved main support layer 36 thus may have better conformity to the shape of the edge portions of wafer 28 and the retaining ring 20.

The grooved main support layer 36 has some advantageous features. The grooved main support layer 36 provides the top pad 32 with a plurality of discrete support points, with each of the protrusions providing one or more support points. Each support point may individually bear the downward pressure, ensuring better conformity to the shapes of the wafer 28 and retaining ring 20. The grooved main support layer 36 thus may support different areas with different shapes during the CMP process.

Furthermore, since each support point is independent from other support points, there is minimal interference, reducing the non-touch area (between top pad 32 and wafer 28) and achieving enhanced uniformity in wafer surface flatness.

In addition, due to the characteristics of independent cylinders, the layers of the sub pad 31 may adopt softer materials, which effectively assists in relieving the downward pressure applied by the retaining ring 20, and hence reducing the occurrence and the severity of retaining-ring-induced top pad deformation.

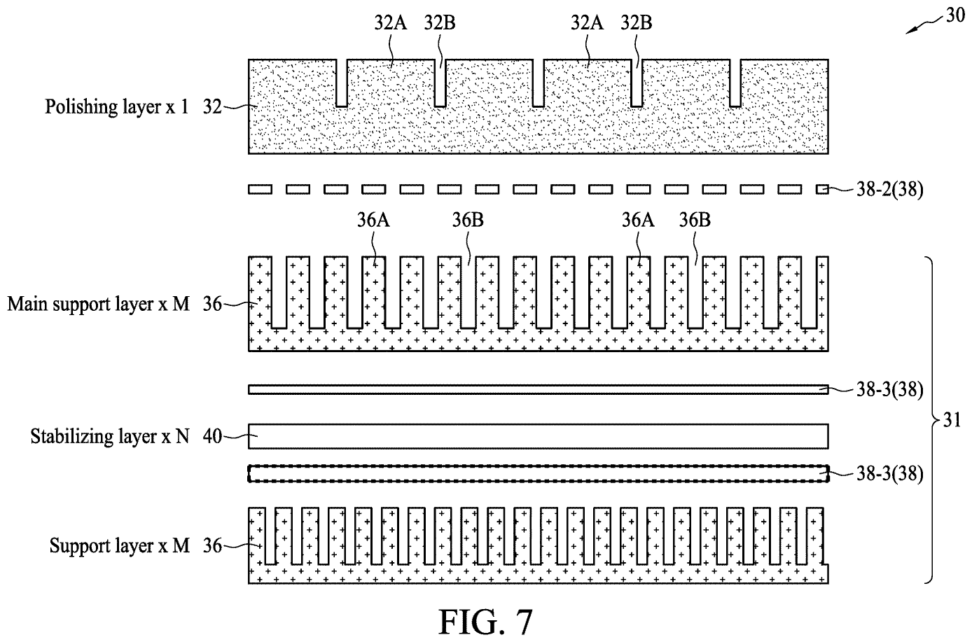

FIG. 7 illustrates the possible stacked layer scheme of a groove-containing sub pad 31 as shown in FIGS. 5 and 6 in accordance with some embodiments. In accordance with some embodiments, the grooved main support layer 36 has a single-layer structure. In accordance with alternative embodiments, the grooved main support layer 36 has a multi-layer structure including a plurality of grooved main support layers 36. Additional adhesive films 38 may be between the stacked grooved main support layers 36, and adhere the plurality of stacked grooved main support layers 36 as a multi-layer structure. The number (M) of the plurality of stacked grooved main support layers 36 may be any number ranging from 1 to 20.

In a groove-containing sub pad 31, the stabilizing layer 40 can consist of or a plurality of layers (with number N), including, for example, about 1 to about 20 layers, which are adhered together by additional adhesive films 38.

In accordance with some embodiments in which one or both of the grooved main support layers 36 and stabilizing layers 40 comprise a plurality of stacked layers, all of the grooved main support layers 36 may be placed over all of the stabilizing layers 40, regardless of the number of the grooved main support layer 36 and the number of the stabilizing layers 40.

In accordance with some embodiments, the grooved main support layer 36 may be a single-layer or may have a multi-layer structure comprising a plurality of main support layers adhered together as a unit.

In accordance with alternative embodiments, one or a plurality of grooved main support layers 36 and one or a plurality of stabilizing layers 40 may be arranged from top to bottom as a unit, regardless of the number of the main support layer 36 and the number of the stabilizing layers 40. The unit may be repeated one or a plurality of times, such as up to about 10 times. For example, FIG. 7 illustrates that more main support layers 36 may be formed under the stabilizing layer 40, which main support layers 36 are in the repeating unit(s). While not shown, more stabilizing layer 40 in the repeating unit(s) may be further formed underlying the illustrated bottom ones of the main support layers 36.

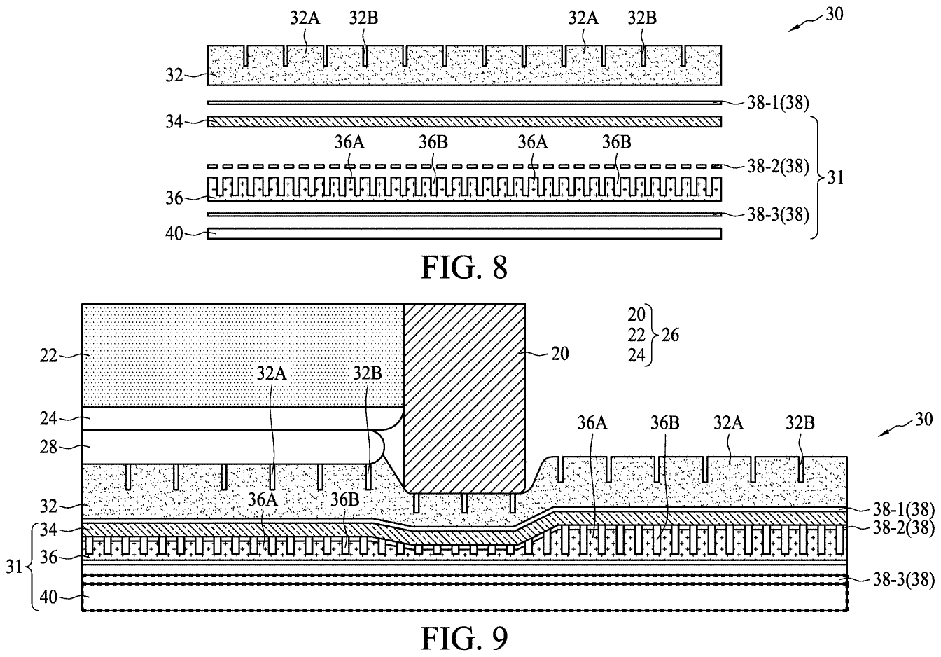

FIG. 8 illustrates the cross-sectional view of a sub pad 31 in accordance with alternative embodiments. The polish pad 30 as shown in FIG. 8 is essentially the same as the polish pad 30 as shown in FIGS. 2 and 5, except that the both of the anti-deformation layer 34 and the grooved main support layer 36 are formed. Accordingly, the embodiments shown in FIG. 8 are the hybrids of the embodiments shown in FIGS. 2 and 5, and the respective sub pad 31 is referred to as a hybrid sub pad 31. The illustrated hybrid sub pad 31 includes anti-deformation layer 34 and grooved main support layer 36, and may or may not include stabilizing layer 40 in accordance with some embodiments. The details of the features shown in FIG. 8 may be found in the embodiments discussed shown in FIGS. 2 through 7, and hence the details are not repeated herein.

In accordance with some embodiments, the anti-deformation layer 34 is formed over the grooved main support layer 36. In accordance with alternative embodiments, the anti-deformation layer 34 may be formed underlying the grooved main support layer 36.

FIG. 9 illustrates parts of the polishing head 26, wafer 28, and polish pad 30 in accordance with some embodiments. The cross-sectional view may be obtained from the cross-section A-A as shown in FIG. 1. As may be realized from the discussion of the embodiments shown in FIGS. 3 and 6, the reduced deformation resulted from the anti-deformation layer and the grooved main support layer 36 may improve the contact of top pad 32 to wafer 28, and the uniformity of the CMP process is improved.

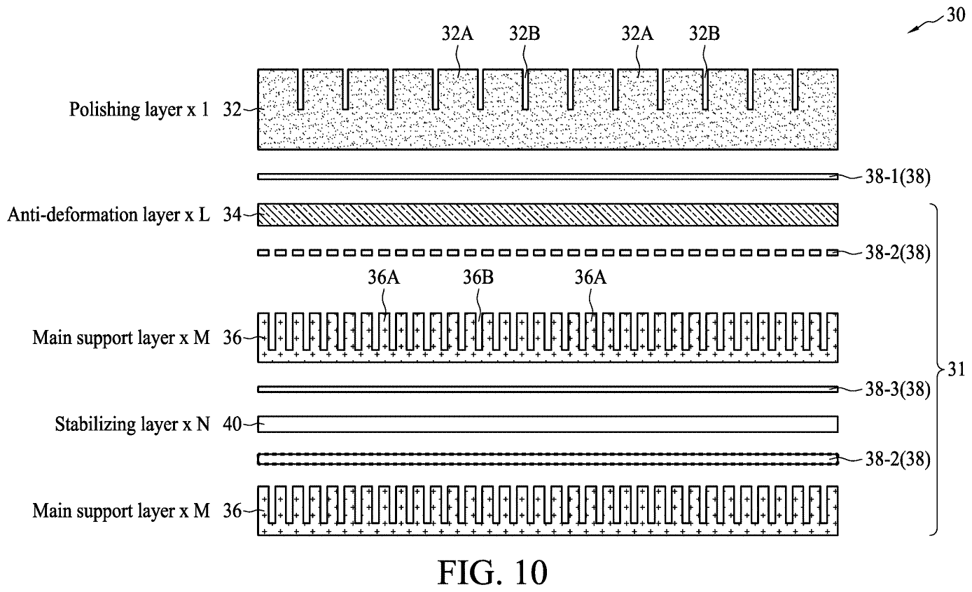

FIG. 10 illustrates the stacking scheme of the number of layers in the hybrid sub pad 31 in accordance with some embodiments, the anti-deformation layers 34 may have flat and porous structures, while the support layers may comprise grooved main support layer(s) 36 with a groove-containing structure and stabilizing layer(s) 40 with a flat and porous structure.

In accordance with some embodiments, each of the anti-deformation layer 34, grooved main support layer 36, and stabilizing layer 40 may have a single layer structure or a multi-layer structure. The details (such as the numbers) of the multi-layer structure of the anti-deformation layer 34 and the stabilizing layer 40 have been discussed referring to FIG. 4, and are not repeated herein. The details (such as the numbers) of the multi-layer structure of the grooved main support layer 36 and the stabilizing layer 40 have been discussed referring to FIG. 7, and are not repeated herein.

In accordance with some embodiments, the topmost sub pad immediately underlying and joined to the top pad 32 through an adhesive film may be an un-grooved main support layer 36 (as shown in FIG. 2) or a grooved main support layer 36 (as shown in FIG. 5).

In accordance with some embodiments in which one or both of anti-deformation layers 34 and grooved main support layer 36 comprise a plurality of stacked layers, all of the anti-deformation layers 34 may be placed over all of the grooved main support layers 36, regardless of the number of the anti-deformation layers 34 and the number of the grooved main support layers 36.

In accordance with alternative embodiments, one or a plurality of anti-deformation layers 34 and one or a plurality of grooved main support layers 36 may be arranged from top to bottom as a unit, regardless of the number of the anti-deformation layers 34 and the number of the main support layer 36. The unit may be repeated one or a plurality of times, for example, for up to about 10 times. For example, FIG. 10 illustrates that more grooved main support layers 36 in the repeating unit(s).

In accordance with some embodiments in which one or both of the main support layer 36 and stabilizing layers 40 comprise a plurality of stacked layers, all of the main support layers 36 may be placed over all of the stabilizing layers 40, regardless of the number of the grooved main support layers 36 and the number of the stabilizing layers 40.

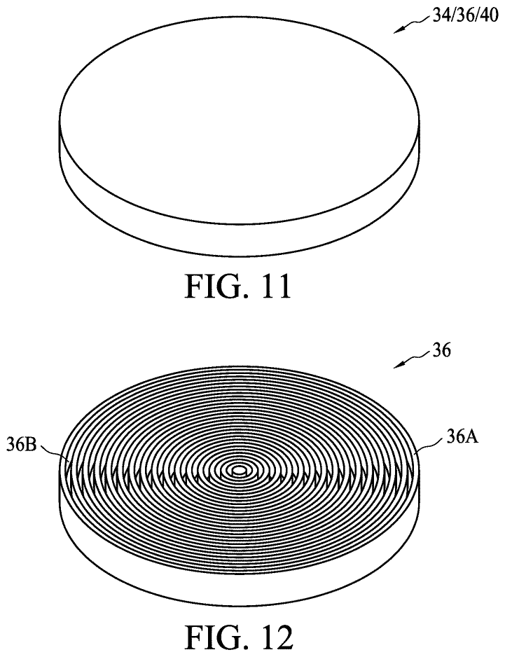

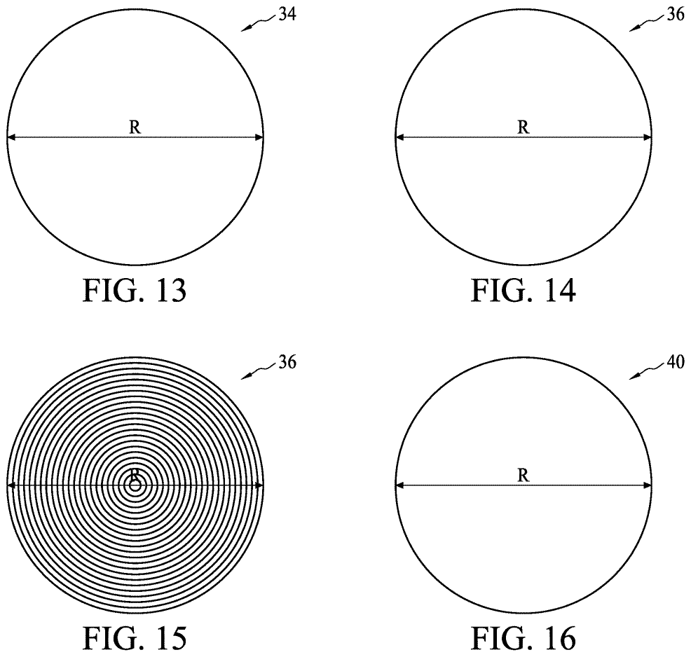

FIGS. 11-20 illustrate the views of some layers in multi-layer sub pad 31 in accordance with some embodiments. FIG. 11 illustrates the perspective view of anti-deformation layer 34, main support layer 36, and/or stabilizing layer 40 in accordance with some embodiments. These layers may be circular plates having a uniform thickness. The top views of anti-deformation layer 34, (un-grooved) main support layer 36, grooved main support layer 36, and/or stabilizing layer 40 are illustrated in FIGS. 13, 14, 15, and 16, respectively.

FIG. 12 illustrates a top view of a grooved main support layer 36 in accordance with some embodiments. The grooved main support layer 36 includes a plurality of concentric protrusions 36A (FIGS. 5 and 20-22) and a plurality of grooves 36B between the plurality of concentric protrusions 36A.

FIGS. 13, 14, 15, and 16 illustrate the top views of anti-deformation layer 34, un-grooved main support layer 36 (FIG. 2), grooved main support layer 36 (FIGS. 5 and 20-22), and stabilizing layer 40 in accordance with some embodiments. The diameters R of these features may be in the range between about 10 inches and about 50 inches.

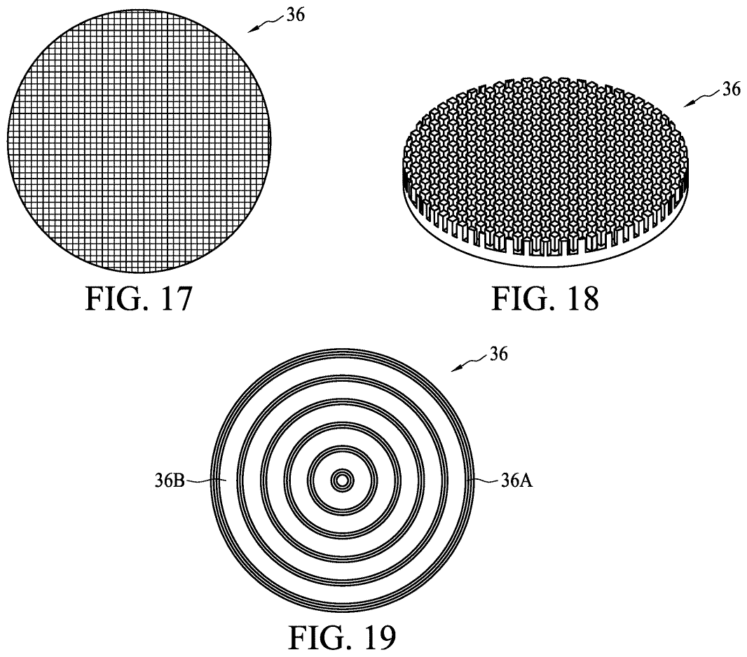

The grooved main support layer 36 (FIG. 15) may have different shapes of protrusions 36A and grooves 36B. For example, as illustrated in FIGS. 12 and 15, the protrusions 36A and grooves 36B may have the shapes of concentric circles. FIGS. 17 and 18 illustrate a top view and a perspective view, respectively, of grooved main support layer 36 in accordance with some embodiments. The protrusions 36A may form an array pattern, and the grooves 36B are interconnected to form a grid pattern (a continuous groove) separating the protrusions 36A into discrete portions.

FIG. 19 illustrates a top view of a grooved main support layer 36 including protrusions 36A and grooves 36B. The protrusions 36A and grooves 36B form concentric rings. The number of protrusions 36A may be in the range between 2 and about 20. In accordance with some embodiments, the protrusions 36A may form a plurality of groups, each including a plurality of protrusions 36A, with the inner-group spacings of protrusions 36A being smaller than inter-group spacings. In accordance with alternative embodiments, the protrusions 36A have a uniform spacing.

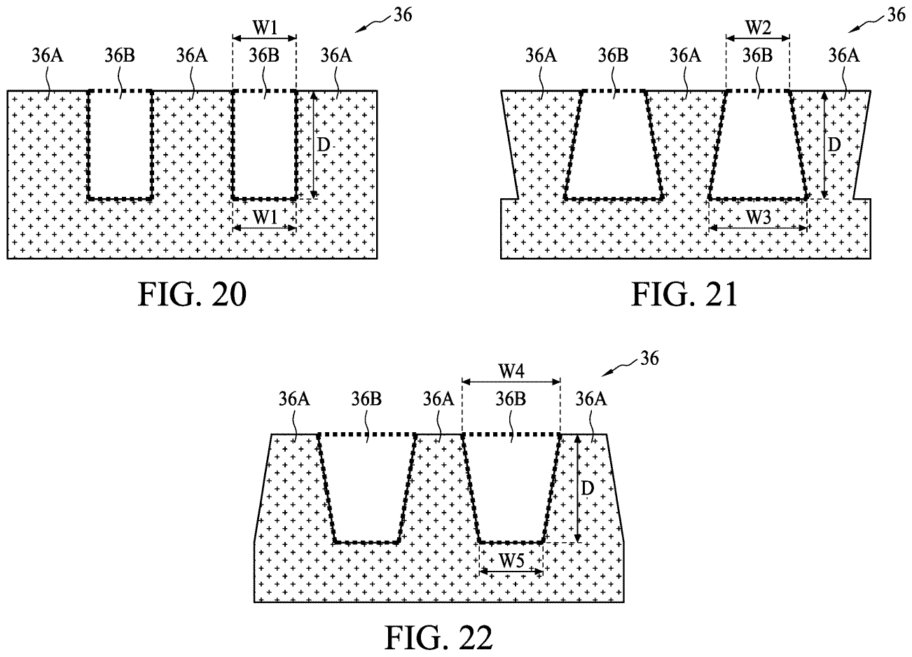

FIGS. 20-22 illustrate the cross-sectional views of some protrusions 36A and grooves 36B in the grooved main support layers 36 in accordance with some embodiments. The grooves 36B may have square shapes, trapezoidal shapes, inverted-trapezoidal shapes, or the like. For the square-shaped grooves 36B as shown in FIG. 20, the depth D may be in the range between about 0.25 mm and about 2.54 mm, and the width W1 may be in the range between about 0.25 mm and about 2.54 mm.

For the trapezoidal-shaped grooves 36B as shown in FIG. 21, the depth D may be in the range between about 0.25 mm and about 2.54 mm, the top width W2 may be in the range between about 0.25 mm and about 1.52 mm, and the bottom width W3 may be in the range between about 1.00 mm and about 2.54 mm.

For the inverted-trapezoidal-shaped grooves 36B as shown in FIG. 22, the depth D may be in the range between about 0.25 mm and about 2.54 mm, the top width W4 may be in the range between about 1.00 mm and about 2.54 mm, and the bottom width W5 may be in the range between about 0.25 mm and about 1.52 mm.

The embodiments of the present disclosure have some advantageous features. By forming the multi-layer sub pad including an anti-deformation layer(s) 34 and/or a grooved main support layer(s), the anti-deformation ability of the sub pads is improved. The uniformity of the CMP process may be improved.

In accordance with some embodiments of the present disclosure, an apparatus comprises a top pad comprising a first plurality of protrusions and a first plurality of grooves between the first plurality of protrusions; a first adhesive film underlying the top pad; an anti-deformation layer underlying and attached to the top pad through the first adhesive film, wherein the anti-deformation layer has a first hardness; a second adhesive film underlying the anti-deformation layer; and a main support layer underlying and attached to the top pad through the second adhesive film, wherein the main support layer has a second hardness lower than the first hardness.

In an embodiment, the first hardness is greater than the second hardness by a shore A difference greater than about 30. In an embodiment, the apparatus further comprises a third adhesive film underlying the main support layer; and a stabilizing layer underlying and attached to the main support layer through the third adhesive film. In an embodiment, the stabilizing layer has a third hardness greater than the second hardness. In an embodiment, the anti-deformation layer is an un-grooved layer. In an embodiment, the main support layer is an un-grooved layer.

In an embodiment, the main support layer comprises a second plurality of protrusions; and a second plurality of grooves between the second plurality of protrusions. In an embodiment, the first plurality of grooves have a first pitch, and the second plurality of grooves have a second pitch smaller than the first pitch. In an embodiment, the second adhesive film is a blanket film continuously extending over the second plurality of grooves and the second plurality of protrusions. In an embodiment, the second adhesive film comprises a plurality of discrete portions overlapping and contacting the second plurality of protrusions.

In an embodiment, a bottom surface of the anti-deformation layer is exposed to the second plurality of grooves. In an embodiment, the apparatus further comprises a plurality of units underlying and attached to the anti-deformation layer, wherein each of the plurality of units comprises an adhesive film and an additional anti-deformation layer. In an embodiment, the apparatus further comprises a plurality of units underlying and attached to the main support layer, wherein each of the plurality of units comprises an adhesive film and an additional main support layer.

In accordance with some embodiments of the present disclosure, an apparatus comprises a top pad comprising a first plurality of protrusions and a first plurality of grooves between the first plurality of protrusions; an anti-deformation layer underlying the top pad, wherein the anti-deformation layer has a first compressibility value; and a main support layer underlying the anti-deformation layer, wherein the main support layer has a second compressibility value greater than the first compressibility value. In an embodiment, the anti-deformation layer comprises a polymer, and has a greater hardness than the main support layer.

In an embodiment, the main support layer comprises a second plurality of protrusions and a second plurality of grooves separating the second plurality of protrusions. In an embodiment, the second plurality of protrusions and the second plurality of grooves have concentric ring patterns. In an embodiment, the second plurality of protrusions are discrete features, and wherein the second plurality of grooves are interconnected to form a continuous groove encircling the plurality of protrusions.

In accordance with some embodiments of the present disclosure, a apparatus comprises a top pad comprising a first plurality of protrusions and a first plurality of grooves between the first plurality of protrusions; a first adhesive film underlying the top pad; and a grooved main support layer underlying and attached to the top pad through the first adhesive film, wherein the grooved main support layer comprises a second plurality of protrusions and a second plurality of grooves between the second plurality of protrusions. In an embodiment, the first plurality of grooves have a first pitch, and the second plurality of grooves have a second pitch smaller than the first pitch.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a top pad;
a first adhesive film underlying the top pad;
an anti-deformation layer underlying and attached to the top pad through the first adhesive film, wherein the anti-deformation layer has a first hardness;
a second adhesive film underlying the anti-deformation layer;
a main support layer underlying and attached to the second adhesive film, wherein the main support layer has a second hardness different from the first hardness;
a third adhesive film underlying the main support layer; and
a stabilizing layer under the and attached to the third adhesive film, wherein the anti-deformation layer is more rigid than the main support layer and the stabilizing layer, and the main support layer is less rigid than both of the anti-deformation layer and the stabilizing layer.

2. The structure of claim 1, wherein the anti-deformation layer is a planar layer.

3. The structure of claim 1, wherein the main support layer is grooved.

4. The structure of claim 1, wherein the top pad is grooved.

5. The structure of claim 4, wherein the main support layer comprises first grooves with a first pitch, and the top pad comprises second grooves with a second pitch greater than the first pitch.

6. The structure of claim 1, wherein the first hardness is greater than the second hardness by a shore A difference greater than about 30, and the stabilizing layer has a third hardness lower than the first hardness.

7. The structure of claim 1 further comprising a retaining ring over and contacting the top pad.

8. The structure of claim 1 further comprising an additional support layer under the stabilizing layer, wherein the additional support layer is also less rigid than the stabilizing layer.

9. The structure of claim 1, wherein the anti-deformation layer and the main support layer comprise polymers.

10. A structure comprising:
a top pad comprising a first plurality of protrusions and a first plurality of grooves between the first plurality of protrusions;
an anti-deformation layer underlying the top pad, wherein the anti-deformation layer is a planar layer;
a main support layer underlying the anti-deformation layer, wherein the main support layer comprises a planar portion comprising a planar top surface and a planar bottom surface; and
a stabilizing layer underlying the main support layer, wherein the main support layer is softer than both of the anti-deformation layer and the stabilizing layer.

11. The structure of claim 10 further comprising:
a first adhesive film between the anti-deformation layer and the main support layer; and
a second adhesive film between the main support layer and the stabilizing layer.

12. The structure of claim 10, wherein the main support layer further comprises:
a plurality of protrusions over and joined to the planar portion; and
a plurality of grooves between the plurality of protrusions.

13. The structure of claim 10, wherein the main support layer is an un-grooved layer.

14. The structure of claim 10, wherein the anti-deformation layer is an un-grooved layer.

15. The structure of claim 10, wherein the anti-deformation layer is harder than both of the main support layer and the stabilizing layer.

16. A structure comprising:
a top pad comprising a first plurality of protrusions and a first plurality of grooves between the first plurality of protrusions; and
at least one unit under and attached to the top pad, wherein the at least one unit comprises:
an anti-deformation layer, wherein the anti-deformation layer is a planar layer;
a grooved main support layer underlying and attached to the anti-deformation layer, wherein the grooved main support layer comprises a second plurality of protrusions and a second plurality of grooves between the second plurality of protrusions; and
a stabilizing layer underlying and attached to the grooved main support layer, wherein the stabilizing layer is an additional planar layer, and wherein the grooved main support layer is softer than both of the anti-deformation layer and the stabilizing layer.

17. The structure of claim 16 further comprising:
a first adhesive film between the anti-deformation layer and the grooved main support layer; and
a second adhesive film between the grooved main support layer and the stabilizing layer.

18. The structure of claim 16 further comprising an additional unit underlying and attached to the at least one unit, wherein the additional unit repeats a structure of the at least one unit.

19. The structure of claim 16, wherein the anti-deformation layer is more rigid than the grooved main support layer and the stabilizing layer, and the grooved main support layer is less rigid than both of the anti-deformation layer and the stabilizing layer.

20. The structure of claim 16, wherein the first plurality of grooves of the top pad have a first pitch, and the second plurality of protrusions have a second pitch smaller than the first pitch.
